(19) United States
(12) Patent Application Publication
(10) Pub. No.: US 2023/0194724 A1
(43) Pub. Date: Jun. 22, 2023

(54) HIGH-DYNAMIC-RANGE HYBRID SOLID-STATE LiDAR SYSTEM BASED ON TRANSPONDER ARRAY MODULE

(71) Applicant: Beijing Institute of Technology, Beijing (CN)

(72) Inventors: Qun HAO, Beijing (CN); Jie CAO, Beijing (CN); Jingjing LI, Beijing (CN); Kun LI, Beijing (CN); Jiaqi GUO, Beijing (CN); Kaili ZHANG, Beijing (CN)

(73) Assignee: Beijing Institute of Technology, Beijing (CN)

(21) Appl. No.: 17/739,264

(22) Filed: May 9, 2022

(30) Foreign Application Priority Data
Dec. 17, 2021 (CN) 202111561979.6

(51) Int. Cl. G01S 17/894; G02B 26/08; H01L 31/107; G01S 7/481; G01S 7/484; G01S 7/4863

(52) U.S. Cl. CPC G01S 17/894; G01S 7/484; G01S 7/4817; G01S 7/4863; G02B 26/0833; H01L 31/107

(57) ABSTRACT

A high-dynamic-range hybrid solid-state lidar system, which is based on a transponder array module, includes a transmitting system, a transceiver integrated optical system, a one-dimensional scanning device, a detecting system, and an information processing system. An information processing control circuit and a gain control module increase a total amplification factor, in a single timing period, of a gain circuit over time, thereby alleviating an echo signal intensity distortion, and expanding a dynamic ranging range. The system uses the one-dimensional scanning device and the transceiver integrated optical system composed of a circulator, a lens set, and an optical fiber array, so that the optical system is separated from an avalanche photo diode (APD) detector, and focusing is not required. A temperature of a linear APD array is monitored in the detecting system to adjust a reverse bias voltage of an APD correspondingly and alleviate unstable gain caused by a temperature change.

### CROSS REFERENCE TO THERELATED APPLICATIONS

This application is based upon and claims priority to Chinese Patent Application No. 202111561979.6, filed on Dec. 17, 2021, the entire contents of which are incorporated herein by reference.

### TECHNICAL FIELD

The present invention relates to a high-dynamic-range hybrid solid-state lidar system based on a transponder array module, and belongs to the technical field of lidars.

### BACKGROUND

The lidar refers to a radar system that transmits a laser beam to detect the characteristic quantities such as the position and the speed of the target, and works in the infrared spectrum-the ultraviolet spectrum. The transmitting system of the lidar transmits the laser signal, and after the laser signal is reflected or scattered by the target object, the receiving system processes the echo signal for ranging and imaging. The lidar features the high interference resistance, the high resolution, etc., and is thereby widely applied to the field of automatic driving. Currently, the main ranging method of the lidar is the flight time method, which measures the flight time, between the lidar and the target object, of the laser signal, to determine, according to the flight time and the light speed, the position. The traditional lidar features the limited emergent laser power. The too close measurement distance and the too strong optical signal are likely to cause the output saturation of the output signal of the receiving system. The far measurement distance and the too weak optical signal are likely to make the output signal of the receiving system too weak, which is not conducive to the signal processing in the next step and limits the dynamic range. In addition, the traditional lidar features a large occupied space and a complex structural design in consideration of the focusing of the optical system and the detector, resulting in the large size of the lidar and the difficulty in optical-mechanical assembly and adjustment.

### SUMMARY

To solve an insufficient dynamic gain range, a complex structure, and great difficulty in optical-mechanical assembly and adjustment of a current navigation lidar, a main objective of the present invention is to provide a high-dynamic-range hybrid solid-state lidar system based on a transponder array module. The hybrid solid-state lidar system based on a transponder array module realizes reliable and stable ranging and imaging in a high dynamic range, and may expand a dynamic gain range. The present invention simplifies a structure of the lidar, is easy to miniaturize, and reduces difficulty in assembling and adjusting.

The objective of the present invention is achieved through the technical solution as follows:

The high-dynamic-range hybrid solid-state lidar system based on a transponder array module disclosed by the present invention includes a transmitting system, a transceiver integrated optical system, a one-dimensional scanning device, a detecting system, and an information processing system.

The transmitting system is used for outputting an array laser signal. The transmitting system includes a driving circuit, a semiconductor array laser, a light beam collimation optical system, a spectroscope, and a photoelectric detection module.

The transceiver integrated optical system and the one-dimensional scanning device are used for receiving an echo signal reflected by a target object, and the transceiver integrated optical system includes an optical fiber array and a lens set. Single optical fibers in the optical fiber array are arranged according to system requirements, and a resolution of a preset position of the system is adjusted by adjusting arrangement of the optical fibers. The one-dimensional scanning device is preferably a one-dimensional galvanometer, a micro-electro-mechanical system (MEMS) mirror, or a prism. Compared with a traditional transceiver optical system, the transceiver integrated optical system may separate the optical system from an avalanche photo diode (APD) detector, focusing is not required, a lidar features a compact structure, and difficulty in assembling and adjusting, and difficulty in implementing the structure are reduced.

The detecting system is used for converting an optical signal into an electrical signal. The detecting system includes an APD detector, a temperature compensation module, a high-voltage reverse bias circuit, and a protection circuit. The APD detector is optionally a linear array APD, a planar array APD, or a plurality of single-point APD detectors. The APD detector is coupled to the transceiver integrated optical system through the optical fibers, so that requirements on spatial arrangement of the APD detector may be reduced, a system structure is simplified, and the difficulty in assembling and adjusting is reduced. The temperature compensation module is used for detecting a working temperature of an APD and outputting a corresponding signal to adjust the high-voltage reverse bias circuit. An avalanche gain coefficient of the APD is closely related to an applied reverse bias voltage and the working temperature, and avalanche gain is positively related to the reverse bias voltage and negatively related to the working temperature. A temperature sensor is arranged close to the linear APD detector, to acquire a working temperature of the linear APD detector, to convert temperature information into an electrical signal, and further to transmit same to an information processing circuit. In addition, the information processing circuit acquires a voltage of the high-voltage reverse bias circuit, and carries out a comprehensive fitting calculation on the temperature of the APD and the reverse bias voltage, to adjust the reverse bias voltage applied by the high-voltage reverse bias circuit to the APD, so that avalanche gain of the APD is stabilized.

The information processing system is mainly used for 1, controlling triggering of a signal of the transmitting system; 2, amplifying a detection signal of the detecting system, and using an information processing control circuit, and a gain circuit, to enable an amplification factor of a main amplification circuit to be changed over time, thereby effectively alleviating an echo signal intensity distortion, and expanding a dynamic ranging range; and 3, carrying out flight time information and point cloud processing.

The information processing system includes the gain circuit, a time processing circuit, an intensity processing circuit, the information processing control circuit, and an upper computer. The gain circuit converts a photo current signal output by the APD in the detecting system into an amplified voltage signal, the voltage signal being transmitted to the time processing circuit and the intensity processing circuit separately. The time processing circuit processes the signal to obtain a timing stop signal (stop signal), and transmits the timing stop signal to the information processing control circuit, to calculate a flight time, and to further determine a distance of the detection target. The intensity processing circuit carries out peak value holding and acquisition on the voltage signal output by the gain circuit, and further transmits the voltage signal to the information processing control circuit, to obtain intensity information of echo reflected by the detection target.

The information processing control circuit generates a periodic signal related to a time, the signal gating different channels of a gain control module of the main amplification circuit in the gain circuit along with a change of a set time in one period, so that an amplification factor of the gain circuit is changed along with the change of the time in one time period, thereby effectively alleviating the echo signal intensity distortion, and expanding the dynamic ranging range.

A method for implementing a process that the information processing control circuit generates the periodic signal related to the time, and the gain control module is used to adjust the amplification factor of the gain circuit, thereby effectively alleviating the echo signal intensity distortion, and expanding the dynamic ranging range is as follows:
obtaining, based on a lidar equation and a ranging principle of direct detection, received power Pᵣ of the detector,
$${P}_{T} = \frac{{P}_{s} {T}_{A} {}^{2} ρ {D}^{2} {η}_{t} {η}_{r}}{π {c}^{2} {t}^{2}}$$
Pₛ being laser transmitting power, T_{A} being atmospheric transmittance, p being a reflection coefficient of a Lambert target, D being an aperture of a receiving window, ηₜ being an efficiency of a transmitting optical system, ηᵣ being an efficiency of a receiving optical system, c being a light speed, and t being a flight time, and
an output signal U after passing through the gain circuit,
$$U = \frac{{P}_{s} {T}_{A} {}^{2} ρ {D}^{2} {η}_{t} {η}_{r} {R}_{e} {R}_{F} {G}_{t}}{π {c}^{2} {t}^{2}}$$
Rₑ being responsivity, R_{F} being a transimpedance amplification factor, and Gₜ being gain of the main amplification circuit.

As seen from the formula (2) that the output signal of the gain circuit is decreased over time, in the case that the gain is constant, when the detection target is too far, the echo signal is extremely weak and cannot be detected by a post-circuit after being amplified at certain gain, thereby limiting a detection distance of the system; and when the detection target is too close, the echo signal is extremely strong, and exceeds an output range of the amplification circuit when being amplified in the gain circuit, resulting in a saturation distortion, and the echo signal intensity distortion, which are main causes of an insufficient dynamic range of the lidar system.

The information processing control circuit carries out timing with a period T, and divides, according to the detection distance and imaging requirements of the hybrid solid-state lidar, the period T into ii small time periods, time nodes being t₁, t₂, t₃,..., T respectively, and at the time nodes t₁, t₂, t₃,..., T, channels X₁, X₂, X₃,..., Xₙ of a resistance voltage dividing network corresponding to an analog switch chips in the gain control module being gated respectively, thereby changing gain Gₜ, corresponding to each time node in a single timing period, of the main amplification circuit.

$${G}_{t} = \left\{\begin{matrix}{G}_{1} & , & 0 < t \leq {t}_{1} \\ {G}_{2} & , & {t}_{1} < t \leq {t}_{2} \\ {G}_{3} & , & {t}_{2} < t \leq {t}_{3} \\ & & … \\ {G}_{n} & , & {t}_{n - 1} < t \leq T\end{matrix}\right)$$

A total amplification factor, in the single timing period, of the gain circuit is also increased over time, so that the dynamic detection range of the lidar is expanded, and the signal may be subjected to undistorted acquisition and processing by the intensity processing circuit.

A working method of the high-dynamic-range hybrid solid-state lidar system based on a transponder array module disclosed by the present invention is as follows: Under the control of a receiving and processing system, transmitting, by the transmitting system, a pulse laser beam, enabling the pulse laser beam to pass through the transceiver integrated optical system and the one-dimensional scanning device to be formed into an emergent light to irradiate the detection target, enabling signal light reflected by the detection target to pass through the one-dimensional scanning device and the transceiver integrated optical system to irradiate the detecting system, receiving an echo optical signal with information of the detection target and converting, by the detecting system, the echo optical signal into a weak current signal, converting the weak current signal into an amplified voltage signal, and carrying out, by the receiving and processing system, time measurement and intensity detection, transmitting both an intensity signal obtained by the intensity processing circuit and time information obtained by the time processing circuit to the information processing control circuit for further processing, and finally carrying out, by the upper computer, point cloud processing and three-dimensional imaging, that is, realizing reliable and stable ranging and imaging in a high dynamic range.

### The Beneficial Effects

1. According to the hybrid solid-state lidar system based on a transponder array module disclosed by the present invention, the information processing control circuit and the gain control module increase a total amplification factor, in the single timing period, of the gain circuit over time, thereby effectively alleviating the echo signal intensity distortion, expanding the dynamic ranging range, and meeting navigation radar requirements.

2. According to the hybrid solid-state lidar system based on a transponder array module disclosed by the present invention, the transceiver integrated optical system composed of a circulator, the lens set, and the optical fiber array, and the one-dimensional scanning device are used, compared with the traditional transceiver optical system, the optical system may be separated from the APD detector, focusing is not required, the lidar features the simple and compact structure, the difficulty in optical-mechanical assembly and adjustment is reduced, and the present invention is easy to implement.

3. According to the hybrid solid-state lidar system based on a transponder array module disclosed by the present invention, the temperature of the linear APID array is monitored in the detecting system, to correspondingly adjust the reverse bias voltage of the APD, so that unstable gain caused by a temperature change is effectively alleviated.

### BRIEF DESCRIPTION OF THE DRAWINGS

FIG. 1 is a block diagram of a high-dynamic-range hybrid solid-state lidar system based on a transponder array module of the present invention;

FIG. 2 corresponds to a transmitting system in FIG. 1;

FIG. 3 corresponds to a detecting system in FIG. 1;

FIG. 4 corresponds to an information processing system in FIG. 1;

FIG. 5 shows echo signal intensity at different times when gain is constant;

FIG. 6 shows two distortion phenomena occurring when the gain is constant;

FIG. 7 corresponds to a gain circuit in FIG. 4;

FIG. 8 shows a gain change over time of a main amplification circuit; and

FIG. 9 shows output signal intensity of the main amplification circuit after the gain is adjusted.

### DETAILED DESCRIPTION OF THE EMBODIMENTS

To better describe the objectives and advantages of the present invention, Summary of the Invention is further described below with reference to the accompanying drawings and examples. Embodiment 1:

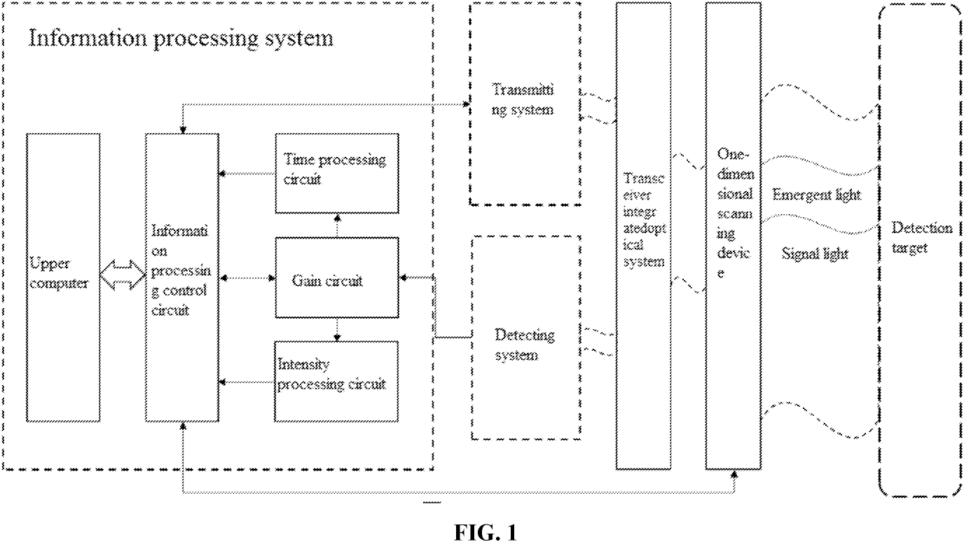

As shown in FIG. 1, a hybrid solid-state lidar system based on a transponder array module disclosed in the present embodiment includes a transmitting system, a transceiver integrated optical system, a one-dimensional scanning device, a detecting system, and an information processing system.

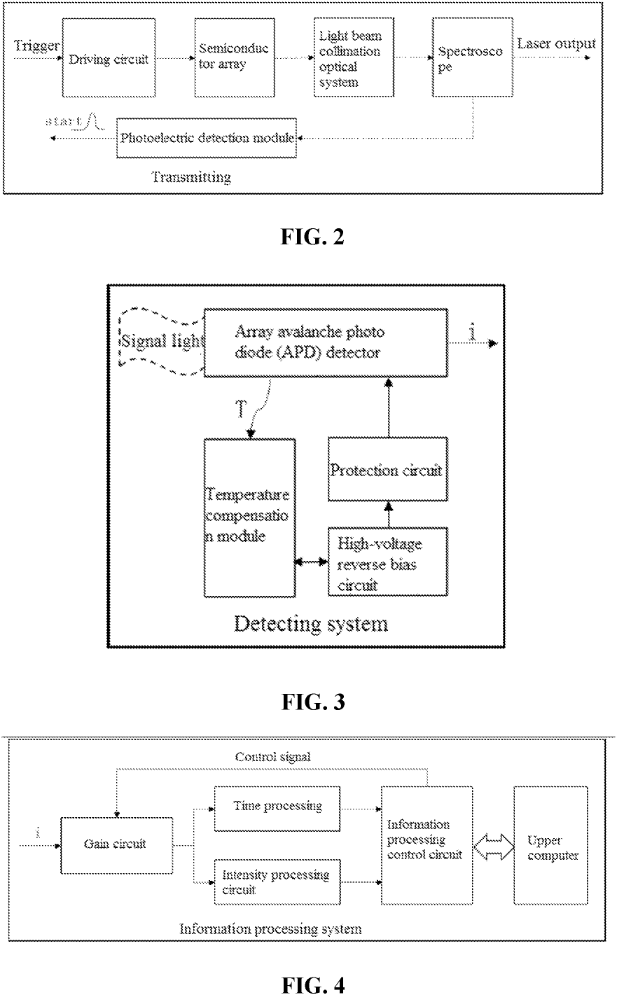

As shown in FIG. 2, the transmitting system is used for outputting an array laser signal, and includes a driving circuit, a semiconductor array laser, a light beam collimation optical system, a spectroscope, and a photoelectric detection module. The information processing system sends a trigger signal with a certain frequency. Under the action of the driving circuit, the semiconductor linear array laser transmits a pulse laser signal, the light beam collimation system collimates a laser, to meet a transmission angle required by a detection target, the spectroscope divides the laser signal into two laser beams at a ratio of 99.5:0.5, a laser signal of a main optical path irradiates the detection target, and a laser signal of a local oscillator optical path irradiates the photoelectric detection module, to generate a timing start signal (start signal).

The transceiver integrated optical system and the one-dimensional scanning device are used for receiving an echo signal reflected by a target object, and the transceiver integrated optical system includes an optical fiber array and a lens set, single optical fibers in the optical fiber array being capable of being arranged at a specific position according to system requirements, and a resolution of the specific position of the system being capable of being adjusted by adjusting arrangement of the optical fibers. The one-dimensional scanning device may be a one-dimensional galvanometer, a micro-electro-mechanical system (MEMS) mirror, or a prism. A laser output by the transmitting system is coupled in the optical fiber array, passes through the lens set and the one-dimensional scanning device, and irradiates the detection target, where the one-dimensional scanning device may be the one-dimensional galvanometer, the MEMS mirror, or the prism. Signal light with information of the detection target passes through the one-dimensional scanning device and the lens set, to be converged at an end surface of the optical fiber array, and then passes through a circulator to irradiate each unit of a linear avalanche photo diode (APD) array coupled to the optical fiber array. Compared with a traditional transceiver optical system, the transceiver integrated optical system may separate the optical system from an APD detector, focusing is not required, a lidar features a compact structure, and difficulty in assembling and adjusting, and difficulty in implementing the structure are reduced.

As shown in FIG. 3, the detecting system is used for converting an optical signal into an electrical signal. The detecting system includes an APD detector, a temperature compensation module, a high-voltage reverse bias circuit, and a protection circuit. The APD detector is optionally a linear array APD, a planar array APD, or a plurality of single-point APD detectors. The APD detector is coupled to the transceiver integrated optical system through the optical fibers, so that requirements on spatial arrangement of the APD detector may be reduced, a system structure is simplified, and the difficulty in assembling and adjusting is reduced. The temperature compensation module is used for detecting a working temperature of an APD and outputting a corresponding signal to adjust the high-voltage reverse bias circuit. An avalanche gain coefficient of the APD is closely related to an applied reverse bias voltage and the working temperature, and avalanche gain is positively related to the reverse bias voltage and negatively related to the working temperature. A temperature sensor is arranged close to the linear APD detector, to acquire a working temperature of the linear APD detector, to convert temperature information into an electrical signal, and further to transmit same to an information processing circuit. In addition, the information processing circuit acquires a voltage of the high-voltage reverse bias circuit, and carries out a comprehensive fitting calculation on the temperature of the APD and the reverse bias voltage, to adjust the reverse bias voltage applied by the high-voltage reverse bias circuit to the APD, so that avalanche gain of the APD is stabilized.

The information processing system is shown in FIG. 4. The information processing system is mainly used for: 1, controlling triggering of a signal of the transmitting system; 2, amplifying a detection signal of the detecting system, and using an information processing control circuit, and a gain circuit, to enable an amplification factor of a main amplification circuit to be changed over time, thereby effectively alleviating an echo signal intensity distortion, and expanding a dynamic ranging range; and 3, carrying out flight time information and point cloud processing.

The information processing system includes the gain circuit, a time processing circuit, an intensity processing circuit, the information processing control circuit, and an upper computer. The gain circuit converts a photocurrent signal output by the APD in the detecting system into an amplified voltage signal, the voltage signal being transmitted to the time processing circuit and the intensity processing circuit separately, the time processing circuit processing the signal to obtain a timing stop signal (stop signal), and transmitting the timing stop signal to the information processing control circuit, to calculate a flight time, and to further determine a distance of the detection target, the intensity processing circuit carrying out peak value holding and acquisition on the voltage signal output by the gain circuit, and further transmitting the voltage signal to the information processing control circuit, to obtain intensity information of echo reflected by the detection target.

The information processing control circuit generates a periodic signal related to a time, the signal gating different channels of a gain control module of the main amplification circuit in the gain circuit along with a change of a set time in one period, so that an amplification factor of the gain circuit is changed along with the change of the time in one time period, thereby effectively alleviating the echo signal intensity distortion, and expanding the dynamic ranging range.

A method for implementing a process that the information processing control circuit generates the periodic signal related to the time, and the gain control module is used to adjust the amplification factor of the gain circuit, thereby effectively alleviating the echo signal intensity distortion, and expanding the dynamic ranging range is as follows:

Received power Pᵣ of the detector is obtained based on a lidar equation and a ranging principle of direct detection,

$${P}_{T} = \frac{{P}_{s} {T}_{A} {}^{2} ρ {D}^{2} {η}_{t} {η}_{r}}{π {c}^{2} {t}^{2}}$$

Pₛ being laser transmitting power, T_{A} being atmospheric transmittance, p being a reflection coefficient of a Lambert target, D being an aperture of a receiving window, ηₜ, being an efficiency of a transmitting optical system, ηᵣ being an efficiency of a receiving optical system, c being a light speed, and t being a flight time.

An output signal U after passing through the gain circuit is obtained,

$$U = \frac{{P}_{s} {T}_{A} {}^{2} ρ {D}^{2} {η}_{t} {η}_{r} {R}_{e} {R}_{F} {G}_{t}}{π {c}^{2} {t}^{2}}$$

Rₑ being responsivity, R_{F} being a transimpedance amplification factor, and Gₜ being gain of the main amplification circuit.

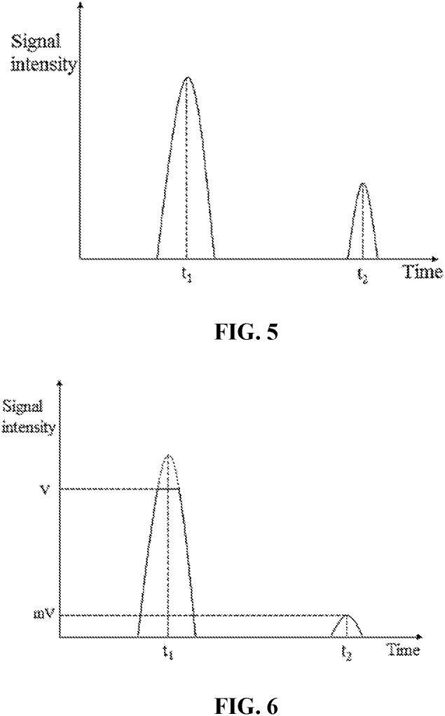

As seen from the formula (2) that the output signal of the gain circuit is decreased over time, FIG. 5 shows echo signal intensity at different times when the gain is constant, and when the detection target is too far, the echo signal is extremely weak and cannot be detected by a post-circuit after being amplified at certain gain, thereby limiting a detection distance of the system; and when the detection target is too close, the echo signal is extremely strong, and exceeds an output range of the amplification circuit when being amplified in the gain circuit, resulting in a saturation distortion occurs, and the echo signal intensity distortion. FIG. 6 shows two distortion phenomena when the gain is constant, which are main causes of an insufficient dynamic range of the lidar system.

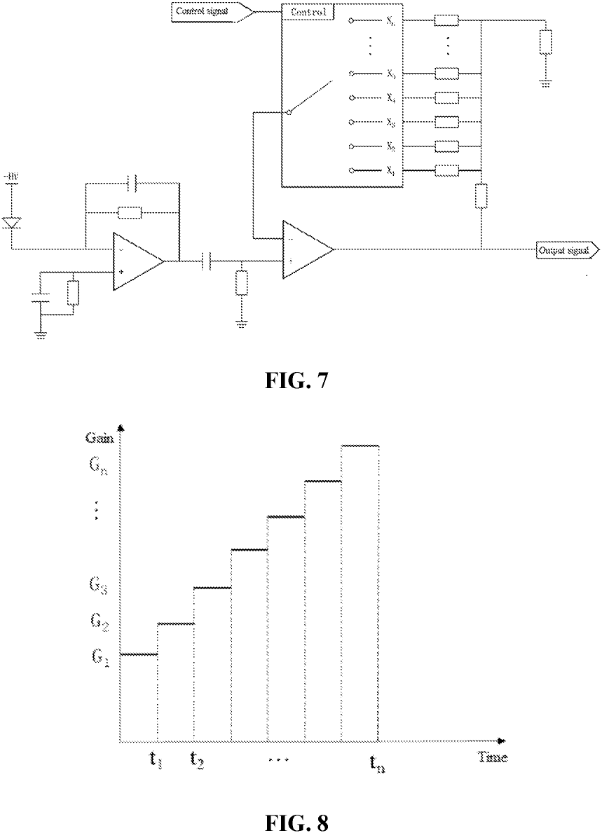

The gain circuit is shown in FIG. 7, and includes a transimpedance amplification circuit, the main amplification circuit, and the gain control module. The information processing control circuit carries out timing with a period T, and divides, according to the detection distance and imaging requirements of the hybrid solid-state lidar, the period T into n small time periods, time nodes being t₁, t₂, t₃,..., T respectively, and at the time nodes t₁, t₂, T, channels X₁, X₂, X₃,..., Xₙ of a resistance voltage dividing network corresponding to an analog switch chip in the gain control module being gated respectively, thereby changing gain Gₜ, corresponding to each time node in a single timing period, of the main amplification circuit.

$${G}_{t} = \left\{\begin{matrix}{G}_{1} & , & 0 < t \leq {t}_{1} \\ {G}_{2} & , & {t}_{1} < t \leq {t}_{2} \\ {G}_{3} & , & {t}_{2} < t \leq {t}_{3} \\ & & … \\ {G}_{n} & , & {t}_{n - 1} < t \leq T\end{matrix}\right)$$

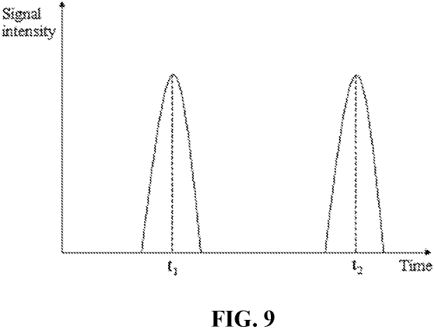

FIG. 8 shows that the gain Gt of the main amplification circuit is changed over time. A total amplification factor, in the single timing period, of the gain circuit is also increased over time, so that the dynamic detection range of the lidar is expanded, and the signal may be subjected to undistorted acquisition and processing by the intensity processing circuit. FIG. 9 shows output signal intensity after the gain is adjusted.

The time processing circuit includes a time identification circuit and a time interval measurement module. A time identification method in the present system is a leading edge threshold comparison method. The method is conducive to implementation of a multi-channel high-speed comparison circuit, features a simple structure, and facilitates a size decrease of a circuit while greatly simplifying complexity of the multi-channel parallel processing circuit. A specific working principle of the leading edge threshold comparison method is as follows: a high-speed comparator is selected, a specific working voltage and a reference voltage are set, and when an input voltage of a non-inverting input end is greater than a reference voltage of an inverting end, an output voltage thereof jumps, so that an output logic high level is close to the working voltage, and a low level is close to 0 V. A TDC-GPX2 multi-channel time interval measurement chip, a field programmable gate array (FPGA) time measurement intellectual property (IP) core or the like is selected as the time interval measurement module, to acquire a level signal output by the time identification circuit, and to calculate a time interval.

A working method of the hybrid solid-state lidar system based on a transponder array module disclosed by the present invention is as follows:

Under the control of a receiving and processing system, the transmitting system transmits a pulse laser beam, the pulse laser beam passes through the transceiver integrated optical system and the one-dimensional scanning device to be formed into an emergent light to irradiate the detection target, and signal light reflected by the detection target passes through the one-dimensional scanning device and the transceiver integrated optical system to irradiate the detecting system. The detecting system receives an echo optical signal with information of the detection target and converts the echo optical signal into a weak current signal, and the receiving and processing system converts the weak current signal into an amplified voltage signal, and carries out time measurement and intensity detection. Finally the information processing control circuit carries out processing and transmits all information to the upper computer.

Both an intensity signal obtained by the intensity processing circuit and time information obtained by the time processing circuit are transmitted to the information processing control circuit for further processing, and finally the upper computer carries out point cloud processing and three-dimensional imaging.

The detailed description above is to further explain the objectives, technical solutions, and beneficial effects of the present invention in detail. It should be understood that what is described above is merely the specific embodiments of the present invention and is not used to limit the scope of protection of the present invention. Any modification, equivalent substitution, improvement, etc., which are made within the spirit and principle of the present invention, should all fall within the scope of protection of the present invention.

What is claimed is:

1. A high-dynamic-range hybrid solid-state lidar system based on a transponder array module, comprising a transmitting system, a transceiver integrated optical system, a one-dimensional scanning device, a detecting system, and an information processing system, wherein
the transmitting system is configured for outputting an array laser signal, and comprises a driving circuit, a semiconductor array laser, a light beam collimation optical system, a spectroscope, and a photoelectric detection module;
the transceiver integrated optical system and the one-dimensional scanning device are configured for receiving an echo signal reflected by a target object; the transceiver integrated optical system comprises an optical fiber array and a lens set, wherein the optical fiber array comprises an arrangement of single optical fibers arranged according to system requirements, a resolution of a preset position of the transceiver integrated optical system is adjusted by adjusting the arrangement of the single optical fibers; and the one-dimensional scanning device is a one-dimensional galvanometer, a micro-electro-mechanical system (MEMS) mirror or a prism; the transceiver integrated optical system can separate the light beam collimation optical system from an avalanche photo diode (APD) detector, focusing is not required, a lidar features a compact structure, and difficulty in assembling and adjusting, and difficulty in implementing the structure are reduced;
the detecting system is configured for converting an optical signal into an electrical signal, and the detecting system comprises the APD detector, a temperature compensation module, a high-voltage reverse bias circuit, and a protection circuit, wherein the APD detector is coupled to the transceiver integrated optical system through the single optical fibers, so that requirements on spatial arrangement of the APD detector are reduced, a system structure can beis simplified, and the difficulty in assembling and adjusting can be reduced,; the temperature compensation module is configured for detecting a working temperature of an APD and outputting a corresponding signal to adjust the high-voltage reverse bias circuit, wherein an avalanche gain coefficient of the APD is closely related to an applied reverse bias voltage and the working temperature, and an avalanche gain is positively related to the reverse bias voltage and negatively related to the working temperature; a temperature sensor is arranged close to the APD detector to acquire a working temperature of the APD detector, to convert temperature information into an electrical signal, and further to transmit the electrical signal of the information to an information processing circuit, and the information processing circuit acquires a voltage of the high-voltage reverse bias circuit, and carries out a comprehensive fitting calculation on the working temperature of the APD and the applied reverse bias voltage, to adjust the reverse bias voltage applied by the high-voltage reverse bias circuit to the APD, so that the avalanche gain of the APD is stabilized;
the information processing system is configured for controlling triggering of the array laser signal of the transmitting system; amplifying a detection signal of the detecting system and using an information processing control circuit and a gain circuit to enable an amplification factor of a main amplification circuit to be changed over time, thereby effectively alleviating an echo signal intensity distortion, and expanding a dynamic ranging range; and carrying out flight time information and point cloud processing;
the information processing system comprises the gain circuit, a time processing circuit, an intensity processing circuit, the information processing control circuit, and an upper computer, wherein the gain circuit converts a photocurrent signal output by the APD in the detecting system into an amplified voltage signal, the amplified voltage signal is transmitted to the time processing circuit and the intensity processing circuit separately; the time processing circuit processes the amplified voltage signal to obtain a timing stop signal, and transmits the timing stop signal to the information processing control circuit to calculate a flight time, and to further determine a distance of a detection target; and the intensity processing circuit carries out peak value holding and acquisition on the amplified voltage signal output by the gain circuit, and further transmits the amplified voltage signal to the information processing control circuit to obtain intensity information of echo reflected by the detection target; and
the information processing control circuit generates a periodic signal related to a time, the signal gating different channels of a gain control module of the main amplification circuit in the gain circuit along with a change of a set time in one period, so that an amplification factor of the gain circuit is changed along with the change of the set time in the one time period, thereby effectively alleviating the echo signal intensity distortion, and expanding the dynamic ranging range.

2. The high-dynamic-range hybrid solid-state lidar system based on the transponder array module according to claim 1, wherein a process that the information processing control circuit generates the periodic signal related to the time, and the gain control module is used to adjust the amplification factor of the gain circuit, thereby effectively alleviating the echo signal intensity distortion, and expanding the dynamic ranging range is implemented by a method comprising:
obtaining received power Pᵣ of the APD detector based on a lidar equation and a ranging principle of direct detection as follows:
$${P}_{r} = \frac{{P}_{s} {T}_{A} {}^{2} ρ {D}^{2} {η}_{t} {η}_{r}}{π {c}^{2} {t}^{2}}$$
wherein Pₛ is laser transmitting power, T_{A} is atmospheric transmittance, ρ is a reflection coefficient of a Lambert target, D is an aperture of a receiving window, ηₜ is an efficiency of a transmitting optical system, ηᵣ being an efficiency of a receiving optical system, c is a light speed, and t is the flight time, and
obtaining an output signal U after passing through the gain circuit as follows:
$$U = \frac{{P}_{s} {T}_{A} {}^{2} ρ {D}^{2} {η}_{t} {η}_{r} {R}_{e} {R}_{F} {G}_{t}}{π {c}^{2} {t}^{2 s}}$$
wherein Rₑ is responsivity, R_{F} is a transimpedance amplification factor, and Gₜ is gain of the main amplification circuit,
wherein in the formula (2), the output signal of the gain circuit is decreased over time, in the case that the gain is constant, when the detection target is too far, the echo signal is extremely weak, and is not detected by a post-circuit after being amplified at certain gain, thereby limiting a detection distance of the detection system; when the detection target is too close, the echo signal is extremely strong, and exceeds an output range of the amplification circuit when being amplified in the gain circuit, resulting in a saturation distortion, and the echo signal intensity distortion, which are main causes of an insufficient dynamic range of the lidar system;
the information processing control circuit carrying out timing with a period T, and dividing, according to the detection distance and imaging requirements of the high-dynamic-range hybrid solid-state lidar system, the period T into n small time periods, wherein time nodes are t₁, t₂, t₃,..., T respectively, and at the time nodes t₁, t₂, t₃,..., T, channels X₁, X₂, X₃,..., Xₙ of a resistance voltage dividing network corresponding to an analog switch chip in the gain control module are respectively gated, thereby changing gain Gₜ which is corresponding to each time node in a single timing period of the main amplification circuit as follows:
$${G}_{t} = \left\{\begin{matrix}{G}_{1} & , & 0 < t \leq {t}_{1} \\ {G}_{2} & , & {t}_{1} < t \leq {t}_{2} \\ {G}_{3} & , & {t}_{2} < t \leq {t}_{\begin{matrix}3 \\ ⋯\end{matrix}} \\ {G}_{n} & , & {t}_{n - 1} < t \leq T\end{matrix}\right) ,$$
wherein in the single timing period, a total amplification factor of the gain circuit is increased over time, so that the dynamic detection range of the lidar is expanded, and the signal is subjected to undistorted acquisition and processing by the intensity processing circuit.

3. The high-dynamic-range hybrid solid-state lidar system based on the transponder array module according to claim 1, wherein under a control of a receiving and processing system, the transmitting system transmits a pulse laser beam, the pulse laser beam passes through the transceiver integrated optical system and the one-dimensional scanning device to be formed into an emergent light to irradiate the detection target; signal light reflected by the detection target passes through the one-dimensional scanning device and the transceiver integrated optical system to irradiate the detecting system; the detecting system receives an echo optical signal with information of the detection target, and converts the echo optical signal into a weak current signal; the receiving and processing system converts the weak current signal into an amplified voltage signal, and carries out time measurement and intensity detection; both an intensity signal obtained by the intensity processing circuit and time information obtained by the time processing circuit are transmitted to the information processing control circuit for further processing; and finally, the upper computer carries out the point cloud processing and three-dimensional imaging to realize reliable and stable ranging and imaging in a high dynamic range.

4. The high-dynamic-range hybrid solid-state lidar system based on the transponder array module according to claim 2, wherein under a control of a receiving and processing system, the transmitting system transmits a pulse laser beam, the pulse laser beam passes through the transceiver integrated optical system and the one-dimensional scanning device to be formed into an emergent light to irradiate the detection target; signal light reflected by the detection target passes through the one-dimensional scanning device and the transceiver integrated optical system to irradiate the detecting system; the detecting system receives an echo optical signal with information of the detection target, and converts the echo optical signal into a weak current signal; the receiving and processing system converts the weak current signal into an amplified voltage signal, and carries out time measurement and intensity detection; both an intensity signal obtained by the intensity processing circuit and time information obtained by the time processing circuit are transmitted to the information processing control circuit for further processing; and finally, the upper computer carries out the point cloud processing and three-dimensional imaging.

5. The high-dynamic-range hybrid solid-state lidar system based on the transponder array module according to claim 3, wherein the APD detector is selected from a group consisting of a linear array APD, a planar array APD, or a plurality of single-point APD detectors.

6. The high-dynamic-range hybrid solid-state lidar system based on the transponder array module according to claim 4, wherein the APD detector is selected from a group consisting of a linear array APD, a planar array APD, and a plurality of single-point APD detectors.
